(19) United States
(12) Patent Application Publication
(10) Pub. No.: US 2026/0322072 A1
(43) Pub. Date: Oct. 15, 2026

(54) OPTICAL SEMICONDUCTOR DEVICE, OPTICAL SEMICONDUCTOR DEVICE ARRAY, AND MANUFACTURING METHOD FOR OPTICAL SEMICONDUCTOR DEVICE

(71) Applicant: FURUKAWA ELECTRIC CO., LTD., Tokyo (JP)

(72) Inventors: Kenshiro MATSUSHIMA, Tokyo (JP); Kazuaki KIYOTA, Tokyo (JP)

(73) Assignee: FURUKAWA ELECTRIC CO., LTD., Tokyo (JP)

(21) Appl. No.: 19/691,671

(22) Filed: May 29, 2026

Related U.S. Application Data
(63) Continuation of application No. PCT/JP2025/000656, filed on Jan. 10, 2025.

(30) Foreign Application Priority Data
Feb. 13, 2024 (JP) 2024-019568

(51) Int. Cl. H01S 5/042; H01S 5/0234; H01S 5/40

(52) U.S. Cl. CPC H01S 5/04256; H01S 5/4031; H01S 5/0234

(57) ABSTRACT

An optical semiconductor device includes: a substrate; a first semiconductor layer; an active layer formed on the first semiconductor layer and configured to emit light; a second semiconductor layer formed as an upper layer of the first semiconductor layer and the active layer; a passivation film formed on the second semiconductor layer and having electrical insulation property; a first electrode pad; a light-emitting surface; a waveguide; an electrode contact region having a depth spanning from the top surface up to the first semiconductor layer or up to the substrate; and a second electrode pad connected to the substrate or the first semiconductor layer in the electrode contact region via an electrode formed on a tapered surface having a height difference toward direction parallel to the waveguide.

### CROSS-REFERENCE TO RELATED APPLICATIONS

This application is a continuation of International Application No. PCT/JP2025/000656, filed on Jan. 10, 2025 which claims the benefit of priority of the prior Japanese Patent Application No. 2024-019568, filed on Feb. 13, 2024, the entire contents of which are incorporated herein by reference.

### BACKGROUND

The present disclosure relates to an optical semiconductor device, an optical semiconductor device array, and a manufacturing method for the optical semiconductor device.

In Japanese Patent No. 3230785 is disclosed a configuration of an optical semiconductor device which includes a first-conductivity-type buffer layer that is formed in an island-like manner on a semi-insulating semiconductor substrate; includes an active layer, a second-conductivity-type cladding layer, and a mesa stripe of a layered body, which is made of a second-conductivity-type electrode layer, that are formed on the first conductivity type buffer layer; includes a high-resistance semiconductor buried layer that is buried up to the top surface of the mesa stripe excluding some portion of the first-conductivity-type buffer layer; a first electrode that is connected to the top surface of the mesa stripe; and a second electrode that is drawn out from the first-conductivity-type buffer layer, which is exposed inside a groove formed in the high-resistance semiconductor buried layer, up to the top surface of the high-resistance semiconductor buried layer.

In Japanese Patent No. 5691741, an optical semiconductor device is disclosed in which, on a first-conductivity-type semiconductor layer formed on a semiconductor substrate, a first mesa stripe is formed that has a layered structure formed by sequential layering of at least a semiconductor active layer and a second-conductivity-type semiconductor layer having the opposite conductivity type to the first conductivity type; a first terrace structure is formed that has an inclined surface including a high-resistance semiconductor layer for burying the side surfaces of the first mesa stripe; a second mesa stripe is formed that is an independent mesa stripe parallel to the first mesa stripe and that has the same layered structure to the first mesa stripe; and a second terrace structure is formed that has an inclined surface including a high-resistance semiconductor layer for burying the side surfaces of the second mesa stripe. Moreover, on the flat surface of the first terrace structure, a first electrode is disposed that establishes connection with the second-conductivity-type semiconductor layer of the first mesa stripe; and a second electrode is disposed that establishes connection to the first-conductivity-type semiconductor layer exposed in between the first terrace structure and the second terrace structure and that extends up to the flat portion of the second terrace structure.

### SUMMARY

In the techniques explained above, in the case of configuring a laser array for flip-chip mounting, two pad electrodes are arranged in the arrangement direction of the laser array. Moreover, also in the case in which two pad electrodes are arranged perpendicular to the arrangement direction of the laser array, since the wiring for drawing out an n-type electrode is oriented in the arrangement direction of the laser array, it causes a decline in the scale of integration of the optical semiconductor device. Furthermore, since the buried layer of the waveguide is not doped, there remain unsolved issues regarding the heat dissipation at the time when integration is carried out.

There is a need for a technique by which two flip-chip mountable electrodes and an extraction electrode, which establishes connection from the semiconductor layer more on the substrate side than the active layer to the electrodes, are arranged to be perpendicular to the arrangement direction of the laser array. As a result, the scale of integration of the laser array may be enhanced according to a simple process.

According to one aspect of the present disclosure, there is provided an optical semiconductor device including: a substrate; a first semiconductor layer layered on the substrate and doped in a first conductivity type; an active layer formed on the first semiconductor layer and configured to emit light; a second semiconductor layer formed as an upper layer of the first semiconductor layer and the active layer, the second semiconductor layer being doped in a second conductivity type; a passivation film formed on the second semiconductor layer and having electrical insulation property; a first electrode pad layered on top surface of the passivation film and electrically connected to the second semiconductor layer via an opening formed on the passivation film; a light-emitting surface provided on one of end faces enclosing the active layer; a waveguide extending from the light-emitting surface toward end face opposite to the light-emitting surface, the waveguide including the active layer; an electrode contact region having a depth spanning from the top surface up to the first semiconductor layer or up to the substrate; and a second electrode pad layered on top surface of the passivation film and connected to the substrate or the first semiconductor layer in the electrode contact region via an electrode formed on a tapered surface having a height difference toward direction parallel to the waveguide.

According to another aspect of the present disclosure, there is provided a method of manufacturing an optical semiconductor device including: a first semiconductor layer formed on a substrate and doped in a first conductivity type; an active layer formed on the first semiconductor layer and configured to function as a light emitting unit; a second semiconductor layer formed as an upper layer of the first semiconductor layer and the active layer, the second semiconductor layer being doped in a second conductivity type; a passivation film formed on the second semiconductor layer and having electrical insulation property; a first electrode pad electrically connected to the second semiconductor layer on a top surface of the passivation film; a second electrode pad formed on the top surface of the passivation film; a light-emitting surface provided on one of end faces enclosing the active layer; and a waveguide extending from the light-emitting surface toward end face opposite to the light-emitting surface, the waveguide including the active layer, the method including: forming an electrode contact region having a depth spanning from the top surface to the first semiconductor layer or the substrate; and forming the second electrode pad in such a way that, in the electrode contact region, via an electrode formed on a tapered surface having a height difference toward direction parallel to the waveguide, the second electrode pad is connected to the substrate or the first semiconductor layer.

### BRIEF DESCRIPTION OF THE DRAWINGS

FIG. 1 is an illustrative and schematic planar view of a semiconductor device according to an embodiment;

FIG. 2 is a cross-sectional view of the semiconductor or device along II-II line illustrated in FIG. 1;

FIG. 3 is a cross-sectional view of the semiconductor or device along III-III line illustrated in FIG. 1;

FIG. 4 is a cross-sectional view of the semiconductor or device along IV-IV line illustrated in FIG. 1;

FIG. 5 is a cross-sectional view of the semiconductor or device along V-V line illustrated in FIG. 1; and

FIG. 6 is an illustrative and schematic planar view illustrating a wafer in which the semiconductor devices according to the embodiment are arranged.

### DETAILED DESCRIPTION

An exemplary embodiment is described below with reference to the accompanying drawings. In the whole picture of the embodiment described below, identical or corresponding portions are referred to by the same reference numerals. Moreover, the present disclosure is not limited by the embodiment described below. The configurations explained in the embodiment described below as well as the actions and the results (effects) attributed to the configurations are only exemplary. Thus, the present disclosure may be implemented also using some different configuration than the configurations disclosed in the embodiment described below. Meanwhile, according to the present disclosure, it becomes possible to achieve at least one of various effects and secondary effects) that are attributed to the configurations. In the present written description, ordinal numbers are assigned only for convenience and with the aim of differentiating among the directions and the portions. Thus, the ordinal numbers do not indicate the priority or the sequencing.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other. In the following explanation, the X direction is referred to as the short direction or the width direction. The Y direction is referred to as the longitudinal direction or the direction of extension. The Z direction is referred to as the layering direction or the height direction. Meanwhile, the drawings are schematic diagrams intended for use in the explanation. Thus, in the drawings, the scale and the ratio does not necessarily match with the actual objects.

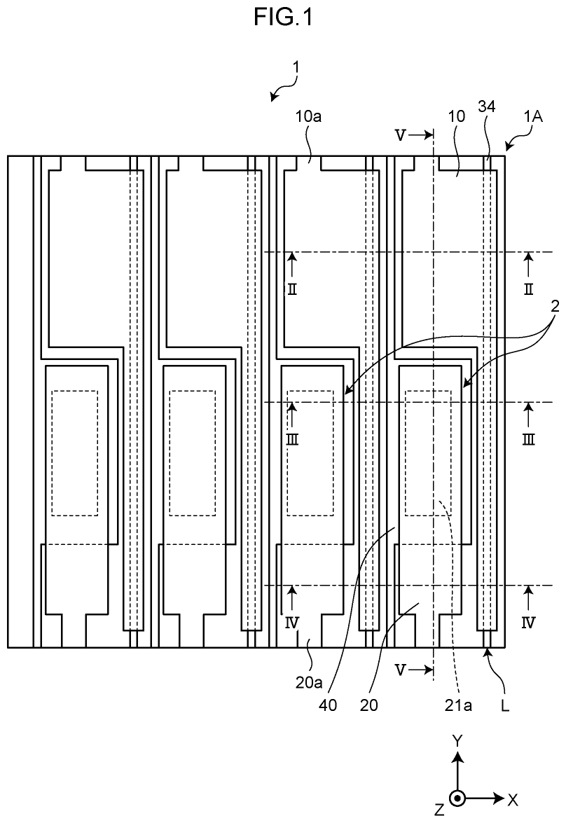

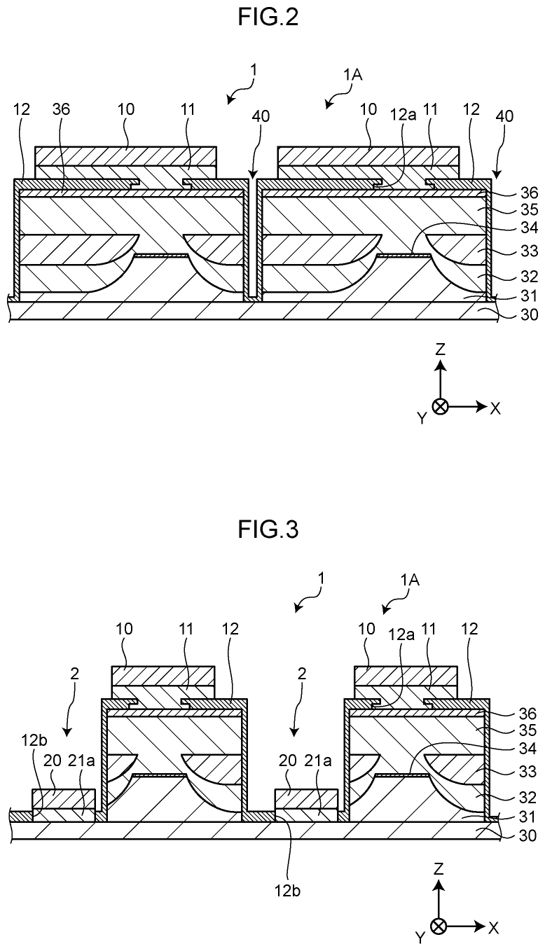

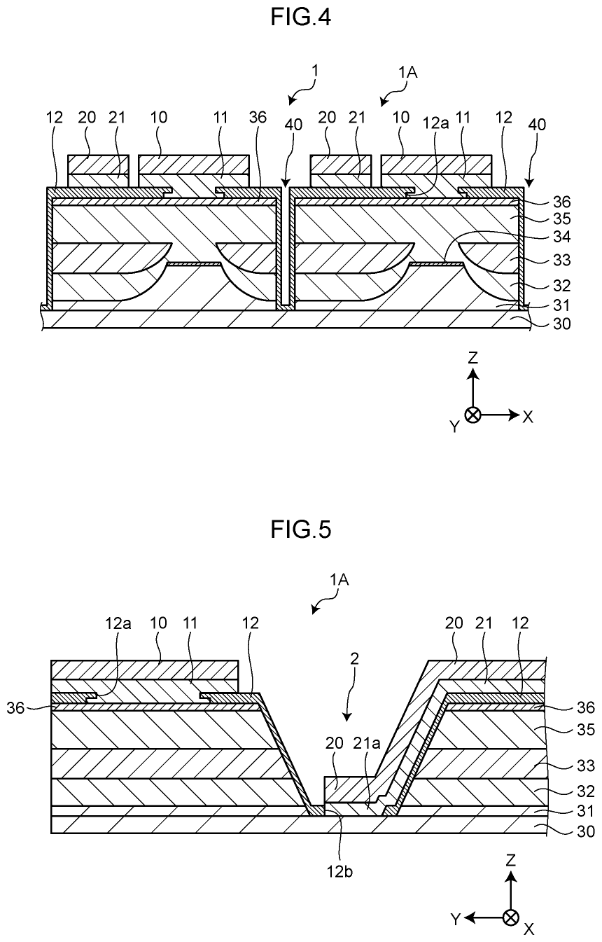

Firstly, the explanation is given about an optical semiconductor device according to the embodiment. FIG. 1 is a top view of an optical device according to the present embodiment. FIGS. 2 to 5 are cross-sectional views along II-II line, III-III line, IV-IV line, and V-V line, respectively, illustrated in FIG. 1.

As illustrated in FIGS. 1 to 5, an optical semiconductor device 1A according to the embodiment is configured as a result of layering of the following: a semiconductor substrate 30; a first semiconductor layer that is layered on the semiconductor substrate 30 and that is made of a lower cladding layer 31 having been doped in, for example, the n-type as a first conductivity type; an active layer 34 that is formed on the lower cladding layer 31 and that emits lights; a second semiconductor layer that is formed as the upper layer of the lower cladding layer 31 and the active layer 34 and that includes an upper cladding layer 35 and a contact layer 36 having been doped in, for example, the p-type as a second conductivity type; a passivation film 12 that is deposited on the contact layer 36 and that has the electrical insulation property; a p-side electrode pad 10 representing a first-type electrode pad that is electrically connected to a p-side electrode 11 representing a first-type electrode on the top surface of the passivation film 12; and an n-side electrode pad 20 representing a second-type electrode pad that is electrically connected to an n-side electrode 21 representing a second-type electrode. The p-side electrode pad 10 is electrically connected to the contact layer 36 through a connection hole 12a formed on the passivation film 12; and includes a waveguide L that has the light-emitting surface present on one of the end faces enclosing the active layer 34, that extends from the light-emitting surface toward the end face present on the opposite side of the light-emitting surface, and that includes the active layer 34. Moreover, an n-side electrode contact region 2 is formed that represents an electrode contact region having the depth spanning from the top surface up to the lower cladding layer 31 representing the first-type semiconductor layer or up to the semiconductor substrate 30. In the n-side electrode contact region 2, the n-side electrode pad 20 is configured with the n-side electrode 21 that is formed on a tapered surface having a height difference toward the direction parallel to the active layer 34 constituting the waveguide L.

In an optical semiconductor array 1 according to the embodiment, a plurality of optical semiconductor devices 1A is arranged. Moreover, electrical isolation grooves 40 are formed that have the depth spanning from the top surface of the passivation film 12 up to the lower cladding layer 31 representing the first semiconductor layer or up to the semiconductor substrate 30. Thus, a plurality of optical semiconductor devices 1A is arranged in the state in which the respective lower cladding layer 31 is electrically separated due to the electrical isolation grooves 40.

As illustrated in FIGS. 2, 3, and 4, the optical semiconductor device 1A according to the present embodiment has a layered structure in which the following layers are layered on the semiconductor substrate 30 made of n-type InP: the lower cladding layer 31 that also serves as the buffer layer and that is made of a layered structure of an n-type InP layer and an n-type InGaAsP layer; the active layer 34 that includes n-type InGaAsP; the upper cladding layer 35 that is made of p-type InP; and the contact layer 36 that is made of p-type InGaAsP. That is, the optical semiconductor device 1A has a thyristor structure in which layers having different conductivity types are alternately layered on a semiconductor layer excluding the vertical direction of the waveguide L (i.e., excluding the X direction). In the upper cladding layer 35, in the longitudinal direction of the optical semiconductor device 1A (i.e., along the Y direction), a diffraction grating layer made of a p-type InGaAsP layer may be formed along the active layer 34. The upper cladding layer 35, which includes the diffraction grating layer; the active layer 34; and the lower cladding layer 31 are processed in a mesa-like shape.

The mesa structure including the active layer 34 has a buried structure attributed to a lower blocking layer 32, which is made of p-type InP and which constitutes the second semiconductor layer, and an upper blocking layer 33, which is made of n-type InP. The lower blocking layer 32 and the upper blocking layer 33 function as current blocking layers. That is, the active layer 34 that is processed in a mesa-like shape functions as an optical waveguide, and includes a buried waveguide structure (BH waveguide structure). Moreover, a main protrusion is formed in such a way that the mesa structure of the active layer 34 is included therein. In the main protrusion, on the contact layer 36, the p-side electrode 11 that is connected to the contact layer 36 is disposed in the connection hole 12a representing an opening, and the p-side electrode pad 10 is disposed at a position drawn out along the array arrangement direction (the X direction).

As illustrated in FIGS. 1 to 4, in the planar view, the light-emitting surface, from which laser emission occurs, is provided on one of the end faces enclosing the top face. In the main protrusion that includes the active layer 34, the waveguide L is provided toward the end face that is opposite to the laser-emitting surface. In the direction parallel to the waveguide L (in the Y direction), the electrical isolation groove 40 is formed that reaches the lower cladding layer 31 or the semiconductor substrate 30. In some portion of the bottom surface of the electrical isolation groove 40, the n-side electrode 21 is formed at a position extended in the array arrangement direction (the X direction).

As illustrated in FIGS. 1 and 5, with reference to the active layer 34, the p-side electrode pad 10 and the n-side electrode pad 20 have their top surfaces to be at a substantially identical height from the active layer 34. That is, the p-side electrode pad 10 and the n-side electrode pad 20 are formed to have their top surfaces present in the substantially identical plane. The main protrusion constitutes a light emitting unit that emits a laser light in response to the injection of an electrical current.

Meanwhile, in the top surface, the n-side electrode contact region 2 is provided to have the depth up to the lower cladding layer 31, which represents the first semiconductor layer, or up to the semiconductor substrate 30. In the n-side electrode contact region 2, at a position drawn out along the perpendicular direction with respect to the array arrangement direction (the X direction) (i.e., drawn out along the Y direction), a contact region 21a is formed in which either the lower cladding layer 31 or the semiconductor substrate 30 is electrically connected to the n-side electrode 21. That is, in the contact region 21a, the n-side electrode pad 20 and the n-side electrode 21, which extend in the Y direction, are electrically connected either to the lower cladding layer 31 or to the semiconductor substrate 30. From the n-side electrode contact region 2, due to the n-side electrode 21 that is formed on a tapered surface having a height difference toward the direction parallel to the active layer 34 (the Y direction) constituting the waveguide L, the n-side electrode pad 20 is connected inside the contact region 21a.

Moreover, due to the electrical isolation grooves 40, between the neighboring optical semiconductor devices 1A, at least the lower blocking layer 32, which serves as the second semiconductor layer, gets electrically separated from the upper cladding layer 35. Thus, the electrical isolation grooves 40 either may be etched to have the depth up to midway of the lower blocking layer 32, or may be etched to have the depth up to the semiconductor substrate 30. In the lower layer of the lower cladding layer 31, when a semi-insulating layer (not illustrated) is further included, the depth at which the n-side electrode 21 makes contact may be extended be up to the lower cladding layer 31, so that the n-side region may also be electrically separated.

Alternatively, when the semiconductor substrate 30 is made of a different conductivity type (for example, the p-type) than the lower cladding layer 31 representing a semi-insulating substrate and serving as the first semiconductor layer, the electrical isolation grooves 40 may be formed to have the depth up to or beyond the lower cladding layer 31. In that case, the lower cladding layer 31, which serves as the first semiconductor layer, of the neighboring optical semiconductor device 1A in the laser array gets separated from the lower blocking layer 32, which serves as the second semiconductor layer, and the upper cladding layer 35. As a result, the excess current path may be cut off, and the carrier injection efficiency may be enhanced, thereby making it a desirable condition.

Given below is the explanation of an example of a manufacturing method for the optical semiconductor device configured in the manner explained above. Firstly, on the semiconductor substrate 30 made of InP, the crystal growth process is sequentially implemented in the following layers: the lower cladding layer 31 having the layered structure that includes an n-type InP layer; the active layer 34 having the layered structure that includes a GaInAsP layer; the upper cladding layer 35 having the layered structure that includes a p-type InP layer; and the diffraction grating layer made of GaInAsP.

Then, on the substrate having the diffraction grating layer formed thereon, the crystal growth process is implemented in, for example, an insulating layer made of silicon nitride (SiN). Subsequently, a resist film is formed on the insulating layer that has been grown. Then, a diffraction grating pattern is formed on the resist film using an electron beam lithography device, and etching is performed on the insulating layer to transfer the diffraction grating pattern. After the resist film is removed, etching is performed on the diffraction grating layer using, for example, a dry etching device, so that a diffraction grating is formed. Subsequently, after the insulating layer is removed, the crystal growth process is implemented in the layer in which the diffraction grating layer is to be buried.

After the resist film is subjected to patterning so as to ensure that the mesa region of the active layer 34 remains intact, etching is performed to remove the insulating layer excluding the insulating layer on the active layer mesa region. After the remaining resist film is removed, etching is performed to form the active layer 34 in the shape of a mesa stripe.

Subsequently, the crystal growth process is sequentially implemented in the lower blocking layer 32 made of p-type InP and the upper blocking layer 33 made of an n-type InP layer, and a burying structure for the active layer mesa is formed. As a result, the active layer 34 gets processed in the shape of a mesa stripe, and a buried waveguide structure is formed that functions as an optical waveguide. Then, after the insulating layer is removed, the upper cladding layer 35 made of p-type InP and the contact layer 36 having a layered structure including a p-type GaInAsP layer are sequentially subjected to crystal growth.

Subsequently, a resist film is formed on the contact layer 36 that has subjected to crystal growth, and patterning is performed in the shape of the electrical isolation groove 40. Then, etching is performed to remove some portion of the contact layer 36, the upper cladding layer 35, the upper blocking layer 33, and the lower blocking layer 32; and accordingly the electrical isolation groove 40 is formed and the n-side electrode contact region 2 is formed. At that time, an anisotropic etchant such as hydrochloric acid (HCL) is selected, and a tapered surface is formed that has a height difference from the bottom portion of the n-side electrode contact region 2 toward the contact layer 36.

Subsequently, after an insulating film made of, for example, silicon nitride (SiN) is formed on the entire surface, a resist film is formed on the insulating film, and patterning is performed on the contact surface of the p-side electrode 11 and the n-side electrode 21. Then, the post-patterning resist film is used as a mask and etching is performed on the insulating film, and after that the resist film is removed.

Subsequently, on the contact layer 36 running along the waveguide, the p-side electrode 11 having a layered structure including Au/AuZn is formed using, for example, the deposition liftoff method. Then, in the n-side electrode contact region 2, the n-side electrode 21 having a layered structure including AuGe/Ni/Au is formed using, for example, the deposition liftoff method.

Subsequently, gold (Au) plating is performed on the upper layer of the p-side electrode 11 and the n-side electrode 21, and the p-side electrode pad 10 and the n-side electrode pad 20 are formed together. As illustrated in FIG. 1, in order to ensure that the p-side electrode pad 10 and the n-side electrode pad 20 may be formed using plating in an integrated manner, protrusion patterns 10a and 20a are formed in such a way that the p-side electrode pad 10 and the n-side electrode pad 20 become continuous in the other optical semiconductor device 1A that is neighboring in the perpendicular direction to the arrangement direction (i.e., neighboring in the Y direction). The protrusion pattern 10a is made of a metallic wiring extending from the p-side electrode pad 10, and the protrusion pattern 20a is made of a metallic wiring extending from the n-side electrode pad 20. That is, in the stage pervious to separating and cutting the optical semiconductor devices 1A from each other, since the p-side electrode pad 10 and the n-side electrode pad 20 are continuous due to the protrusion patterns 10a and 20a, it becomes possible to perform plating.

Then, the semiconductor substrate 30 is polished to a predetermined thickness. Subsequently, for example, heat treatment is performed at about 400 ° C. As a result, an ohmic contact is established between the p-side electrode 11 and the contact layer 36, which is a semiconductor layer adjacent to the p-side electrode 11. Moreover, an ohmic contact is established between the n-side electrode 21 and either the lower cladding layer 31, which is a semiconductor layer adjacent to the n-side electrode 21, or the semiconductor substrate 30.

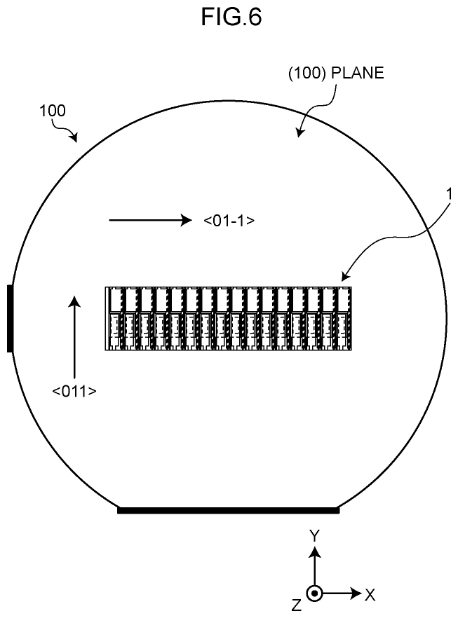

FIG. 6 is a planar view illustrating a semiconductor wafer 100 in which the optical semiconductor devices 1A are arranged along a predetermined direction. As illustrated in FIG. 6, the surface of the semiconductor wafer 100 represents the (100) plane; the longitudinal direction (the Y direction) of a plurality of optical semiconductor devices 1A becomes the <011> crystal direction; and the arrangement direction (the X direction) that is perpendicular to the longitudinal direction is treated as the <01-1>crystal direction. In the semiconductor wafer 100 in which a plurality of optical semiconductor devices 1A is formed, end faces are formed using cleavages; an anti-reflective coating is applied on the output side; and a high-reflective coating is applied on the opposite side. As a result, the optical semiconductor devices 1A illustrated in FIG. 1 are formed.

According to the embodiment as described above, the p-side electrode pad 10 and the n-side electrode pad 20, which are the two flip-chip mountable electrode pads, and an extraction electrode meant for establishing connection from the lower cladding layer 31, which is a semiconductor layer more on the side of the semiconductor substrate 30 than the active layer 34, to the n-side electrode 21 may be arranged along the direction perpendicular to the laser array arrangement direction (the X direction) (i.e., may be arranged along the Y direction). Hence, the scale of integration of the laser array may be enhanced according to a simple process.

According to the present disclosure, it becomes possible to enhance the scale of integration of a laser array according to a simple process.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical semiconductor device comprising:
a substrate;
a first semiconductor layer layered on the substrate and doped in a first conductivity type;
an active layer formed on the first semiconductor layer and configured to emit light;
a second semiconductor layer formed as an upper layer of the first semiconductor layer and the active layer, the second semiconductor layer being doped in a second conductivity type;
a passivation film formed on the second semiconductor layer and having electrical insulation property;
a first electrode pad layered on top surface of the passivation film and electrically connected to the second semiconductor layer via an opening formed on the passivation film;
a light-emitting surface provided on one of end faces enclosing the active layer;
a waveguide extending from the light-emitting surface toward an end face opposite to the light-emitting surface, the waveguide including the active layer;
an electrode contact region having a depth spanning from the top surface up to the first semiconductor layer or up to the substrate; and
a second electrode pad layered on top surface of the passivation film and connected to the substrate or the first semiconductor layer in the electrode contact region via an electrode formed on a tapered surface having a height difference toward direction parallel to the waveguide.

2. The optical semiconductor device according to claim 1, wherein a top surface of the first electrode pad and a top surface of the second electrode pad are positioned in substantially identical plane.

3. The optical semiconductor device according to claim 2, wherein, in a planar view, a metallic wiring extending from the first electrode pad and a metallic wiring extending from the second electrode pad are disposed in an end portion of top surface.

4. The optical semiconductor device according to claim 1, further comprising a thyristor structure in which layers having different conductivity types are alternately layered on a semiconductor layer excluding vertical direction of the waveguide.

5. An optical semiconductor device array comprising:
a plurality of the optical semiconductor devices according to claim 1;
an electrical isolation groove having a depth from top surface of the passivation film up to the first semiconductor layer or the substrate; and
a plurality of the optical semiconductor devices arranged in a state in which the second semiconductor layer is electrically separated due to the electrical isolation groove.

6. The optical semiconductor device array according to claim 5, wherein the first semiconductor layer is electrically separated due to the electrical isolation groove.

7. The optical semiconductor device array according to claim 5, wherein, in a planar view, the electrical isolation groove and the electrode contact region are adjacent to each other.

8. The optical semiconductor device array according to claim 5, wherein a depth from the top surface to the electrode contact region is substantially equal to a depth from the top surface to the electrical isolation groove.

9. A method of manufacturing an optical semiconductor device including: a first semiconductor layer formed on a substrate and doped in a first conductivity type; an active layer formed on the first semiconductor layer and configured to function as a light emitting unit; a second semiconductor layer formed as an upper layer of the first semiconductor layer and the active layer, the second semiconductor layer being doped in a second conductivity type; a passivation film formed on the second semiconductor layer and having electrical insulation property; a first electrode pad electrically connected to the second semiconductor layer on a top surface of the passivation film; a second electrode pad formed on the top surface of the passivation film; a light-emitting surface provided on one of end faces enclosing the active layer; and a waveguide extending from the light-emitting surface toward end face opposite to the light-emitting surface, the waveguide including the active layer, the method comprising:
forming an electrode contact region having a depth spanning from the top surface to the first semiconductor layer or the substrate; and
forming the second electrode pad in such a way that, in the electrode contact region, via an electrode formed on a tapered surface having a height difference toward direction parallel to the waveguide, the second electrode pad is connected to the substrate or the first semiconductor layer.
